(19) United States
(12) Patent Application Publication
(10) Pub. No.: US 2023/0043874 A1
(43) Pub. Date: Feb. 9, 2023

(54) SEMICONDUCTOR STRUCTURE AND MANUFACTURING METHOD THEREOF

(71) Applicant: CHANGXIN MEMORY TECHNOLOGIES, INC., Hefei City (CN)

(72) Inventors: Peimeng WANG, Hefei City (CN); Chi-Wei DAI, Hefei City (CN)

(21) Appl. No.: 17/657,817

(22) Filed: Apr. 4, 2022

(30) Foreign Application Priority Data
Aug. 4, 2021 (CN) 202110893037.1

(51) Int. Cl. H01L 21/3065; H01L 21/762; H01L 21/3105

(52) U.S. Cl. CPC H01L 21/30655; H01L 21/76297; H01L 21/31051

(57) ABSTRACT

The present disclosure relates to a semiconductor structure and a manufacturing method thereof. The manufacturing method of a semiconductor structure includes: providing a substrate, where a plurality of contact pads are formed on the substrate; depositing a dielectric layer on the substrate, where the dielectric layer fills gaps between the contact pads and covers the contact pads; and etching the dielectric layer through a plasma etching process to expose the contact pads, where an etching gas used in the plasma etching process includes an oxygen-free etching gas. The manufacturing method can avoid the formation of metal oxides on the contact pads, and avoid residual conductive metal particles or metal compounds on surfaces of the contact pads and the adjacent dielectric layers, which is beneficial to ensure the electrical performance of the semiconductor structure, thereby improving the use reliability of the semiconductor structure.

### CROSS-REFERENCE TO RELATED APPLICATIONS

This application claims the priority of Chinese Patent Application No. 202110893037.1, submitted to the Chinese Intellectual Property Office on Aug. 4, 2021, the disclosure of which is incorporated herein in its entirety by reference.

### TECHNICAL FIELD

The present disclosure relates to the field of semiconductor integrated circuit manufacturing technologies, in particular to a semiconductor structure and a manufacturing method thereof.

### BACKGROUND

As a commonly used semiconductor memory in electronic devices such as computers, a dynamic random access memory (DRAM) includes a plurality of memory cells. Each memory cell includes: a memory capacitor, and a transistor electrically connected to the memory capacitor. The gate of the transistor is used for electrical connection with a word line. The source region of the transistor is used to form a bit line contact region to be electrically connected to a bit line by using a bit line contact structure. The drain region of the transistor is used to form a memory node contact region to be electrically connected to the memory capacitor by using a memory node contact structure. The memory node contact structure includes contact pads.

However, in the process of manufacturing the memory node contact structure, it is usually necessary to perform a plasma etching process to expose the contact pads, which is likely to affect the surface of the contact pads and adversely affects the conductivity of the contact pads.

### SUMMARY

An embodiment of the present disclosure provides a manufacturing method of a semiconductor structure, including the following steps:
providing a substrate, where a plurality of contact pads are formed on the substrate;
depositing a dielectric layer on the substrate, where the dielectric layer fills gaps between the contact pads and covers the contact pads; and
etching the dielectric layer through a plasma etching process to expose the contact pads. An etching gas used in the plasma etching process includes an oxygen-free etching gas.

An embodiment of the present disclosure further provides a semiconductor structure, which is manufactured by using the manufacturing method in the foregoing embodiments.

### BRIEF DESCRIPTION OF THE DRAWINGS

To describe the technical solutions in the embodiments of the present application or in the conventional art more clearly, the following briefly describes the accompanying drawings required for describing the embodiments or the conventional art. Apparently, the accompanying drawings in the following description show merely some embodiments of the present application, and a person of ordinary skill in the art may still derive other accompanying drawings from these accompanying drawings without creative efforts.

FIG. 1 is a flowchart of a manufacturing method of a semiconductor structure according to an embodiment;

FIGS. 2 to 4 are schematic cross-section views of structures obtained in steps of the manufacturing method of a semiconductor structure according to an embodiment, and FIG. 4 is further a schematic structural diagram of a semiconductor structure according to an embodiment;

FIG. 5 is a schematic diagram of etching and removing a dielectric layer according to an embodiment;

FIG. 6 is a flowchart of another manufacturing method of a semiconductor structure according to an embodiment;

FIG. 7 is a schematic diagram of a forming process of a passivation layer according to an embodiment;

FIG. 8 is a schematic diagram of a forming process of another passivation layer according to an embodiment;

FIG. 9 is a schematic diagram of a removing process of a passivation layer according to an embodiment;

FIG. 10 is a flowchart of another manufacturing method of a semiconductor structure according to an embodiment; and

FIG. 11 is a schematic diagram of a process of performing some steps in the manufacturing method of a semiconductor structure according to an embodiment.

### DETAILED DESCRIPTION

To facilitate the understanding of the present application, the present application is described more completely below with reference to the accompanying drawings. The embodiments of the represent disclosure are shown in the accompanying drawings. However, the present application may be embodied in various forms without being limited to the embodiments described herein. These embodiments are provided in order to make the present disclosure more thorough and comprehensive.

Unless otherwise defined, all technical and scientific terms used herein have the same meaning as commonly understood by those skilled in the technical field of the present application. The terms mentioned herein are merely for the purpose of describing specific embodiments, rather than to limit the present application.

It should be understood that when an element or layer is described as “on”, “ adjacent to”, “connected to” or “coupled to” another element or layer, it can be on, adjacent to, connected to, or coupled to the another element or layer directly, or intervening elements or layers may be present. On the contrary, when an element is described as “directly on”, “directly adjacent to”, “directly connected to” or “directly coupled to” another element or layer, there are no intervening elements or layers.

It should be understood that although terms such as first and second may be used to describe various elements, components, regions, layers, doped types and/or sections, these elements, components, regions, layers, doped types and/or sections should not be limited by these terms. These terms are only used to distinguish one element, component, region, layer, doped type or section from another element, component, region, layer, doped type or section. Therefore, without departing from the teachings of the present disclosure, the first element, component, region, layer, doped type or section discussed below may a second element, component, region, layer or section.

Spatial relationship terms such as “under”, “beneath”, “lower”, “below”, “above”, and “upper” can be used herein to describe the relationship shown in the figure between one element or feature and another element or feature. It should be understood that in addition to the orientations shown in the figure, the spatial relationship terms further include different orientations of used and operated devices. For example, if a device in the accompanying drawings is turned over and described as being “beneath another element”, “below it”, or “under it”, the device or feature is oriented “on” the another element or feature. Therefore, the exemplary terms “beneath” and “under” may include two orientations of above and below. In addition, the device may further include other orientations (for example, a rotation by 90 degrees or other orientations), and the spatial description used herein is interpreted accordingly.

In this specification, the singular forms of “a”, “an” and “the/this” may also include plural forms, unless clearly indicated otherwise. It should also be understood that the terms such as “including/comprising” and “having” indicate the existence of the stated features, wholes, steps, operations, components, parts or combinations thereof. However, these terms do not exclude the possibility of the existence of one or more other features, wholes, steps, operations, components, parts or combinations thereof. In this case, in this specification, the term “and/or” includes any and all combinations of related listed items.

Embodiments of the present disclosure are described herein with reference to cross-sectional illustrations that are schematic diagrams of idealized embodiments (and intermediate structures) of the present disclosure, such that variations shown in the shapes can be contemplated due to, for example, manufacturing techniques and/or tolerances. Therefore, the embodiments of the present disclosure should not be limited to the specific shapes of the regions shown herein, but include shape deviations due to, for example, manufacturing technologies. The regions shown in the figure are schematic in nature their shapes are not intended to show the actual shapes of the regions of the device and limit the scope of the present disclosure.

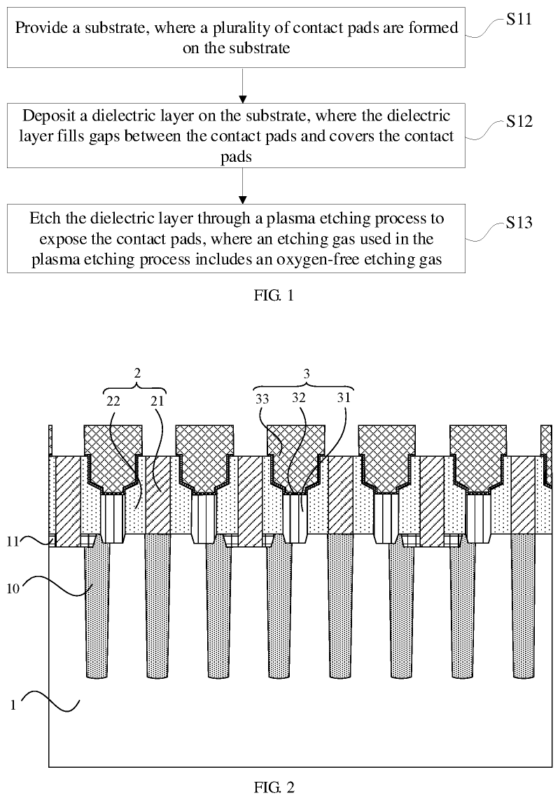

With reference to FIG. 1, an embodiment of the present disclosure provides a manufacturing method of a semiconductor structure, including the following steps:

S11: Provide a substrate, where a plurality of contact pads are formed on the substrate;

S12: Deposit a dielectric layer on the substrate, where the dielectric layer fills gaps between the contact pads and covers the contact pads; and

S13: Etch the dielectric layer through a plasma etching process to expose the contact pads. An etching gas used in the plasma etching process includes an oxygen-free etching gas.

In the embodiments of the present disclosure, the etching gas used for etching the dielectric layer is an oxygen-free etching gas, to avoid the formation of oxides on the exposed surfaces of the contact pads, thereby preventing the oxides from adversely affecting the conductivity of the contact pads.

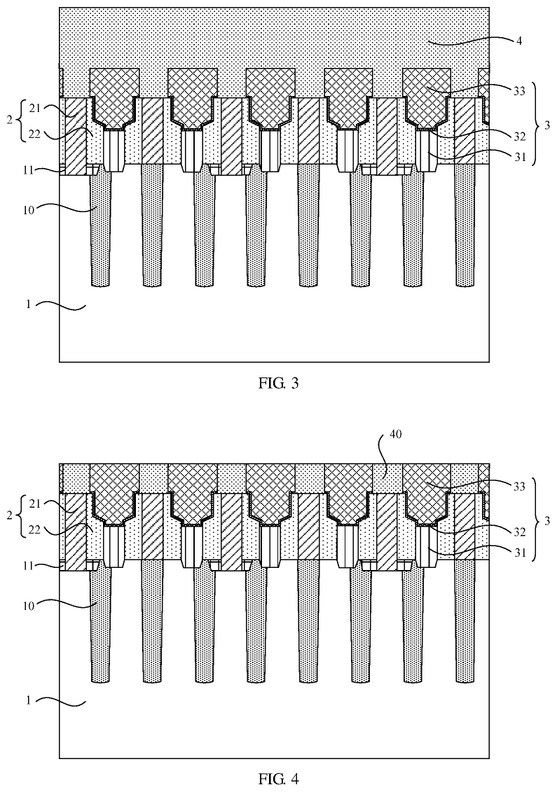

In step S11, with reference to S11 in FIG. 1 and FIG. 2, a substrate 1 is provided, and a plurality of contact pads 33 are formed on the substrate 1.

In one embodiment, the substrate 1 includes but is not limited to a silicon substrate or a silicon-based substrate.

In one embodiment, the contact pads 33 are formation parts of the memory node contact structure 3. When the plurality of contact pads 33 are formed on the substrate 1, a plurality of bit lines 2 arranged discretely in parallel are formed on the substrate 1. A memory node contact structure 3 is formed between adjacent bit lines 2.

As shown in FIG. 2, shallow trench isolation structures 10 are disposed in the substrate 1. The shallow trench isolation structures 10 can separate a plurality of active regions arranged in an array in the substrate 1. The active regions include source regions and drain regions. The shallow trench isolation structure 10 is, for example, a silicon oxide (SiO₂) isolation structure. A material of the active regions is, for example, poly-Si. The source and drain regions of the active regions are respectively different doped regions of poly-Si.

The bit lines 2 are formed on the substrate 1, and each include a bit line structure 21 and a sidewall structure 22. The bit line structure 21 includes: a conductive portion coupled to the source region correspondingly, and an insulating medium covering the top surface of the conductive portion. The sidewall structure 22 includes at least one insulating dielectric layer. The materials of the insulating medium and the insulating dielectric layer are, for example, SiO₂ and/or silicon nitride (Si₃N₄). In addition, as shown in FIG. 2, bottoms of some bit line structures 21 protrude into the substrate 1 to be coupled to the corresponding source regions, and the peripheral sides of the bottoms of the bit line structures 21 are also provided with insulating layers 11 filled in the substrate 1. The insulating layer 11 is, for example, a SiO₂ layer or a Si₃N₄ layer. The insulating layer 11 can be used for insulating the bit line structure 21 and the word line buried in the substrate 1.

With reference to FIG. 2, the memory node contact structure 3 is formed between adjacent bit lines 2. The memory node contact structure 3 includes a contact plug 31, an adhesive layer 32 and the contact pad 33. The contact plug 31 is correspondingly coupled to the drain region, and the material of the contact plug 31 may include but is not only limited to poly-Si. The adhesive layer 32 is located between the contact pad 33 and the contact plug 31 and between the contact pad 33 and the sidewall structure 22 of the bit line 2. The material of the adhesive layer 32 may include but is not only limited to titanium nitride (TiN). The top surface of the contact pad 33 is higher than that of the bit line 2, and there is a gap between every two adjacent contact pads 33. The material of the contact pad 33 is, for example at least one from the group consisting of polysilicon (poly-Si), tungsten (W), cobalt (Co), molybdenum (Mo), tantalum (Ta), titanium (Ti), ruthenium (Ru), rhodium (Rh), copper (Cu), iron (Fe), manganese (Mn), vanadium (V), niobium (Nb), hafnium (Hf), zirconium (Zr), yttrium (Y), aluminum (Al), tin (Sn), chromium (Cr) and lanthanum (La).

In some embodiments, a material of the contact pad 33 is W. Therefore, it can be ensured that the contact pad 33 has a lower resistance value and higher stability.

For ease of description, in the following embodiments, schematic description is made by using the material of the contact pad 33 is W. For a case that the material of the contact pad 33 is another material, reference may be made to the example in which the material of the contact pad 33 is W.

In step S12, with reference to S12 in FIG. 1 and FIG. 3, a dielectric layer 4 is deposited on the substrate 1, where the dielectric layer 4 fills a gap between every two contact pads 33 and covers the contact pads 33.

In some embodiments, the dielectric layer 4 may be formed by using the deposition process or another process. The dielectric layer 4 may include but is not limited to a nitride layer such as a Si₃N₄ layer. The thickness of the dielectric layer 4 may be set according to an actual requirement.

In step S13, with reference to S13 in FIG. 1 and FIG. 4 and FIG. 5, the dielectric layer 4 is etched through a plasma etching process to expose the contact pad 33. An etching gas used in the plasma etching process includes an oxygen-free etching gas.

In this case, after the dielectric layer 4 is etched, a part of the dielectric layer 4 that is not removed through etching is the insulation portion 40 located between adjacent contact pads 33. The insulation portion 40 insulates adjacent contact pads 33.

In addition, the oxygen-free etching gas is referred to as a gas that does not include oxygen O₂ and does not generate the oxygen plasma. The specific type of the oxygen-free etching gas can be determined according to the selected material of the to-be-etched dielectric layer 4.

For example, the dielectric layer 4 is a silicon nitride layer. The etching gas used in the plasma etching process includes: carbon tetrafluoride (CF₄) and trifluoromethane (CHF₃).

For example, the dielectric layer 4 is a silicon nitride layer. The etching gas used in the plasma etching process is CF4, CHF₃ and chlorine (Cl₂).

For example, the dielectric layer 4 is a silicon nitride layer. The etching gas used in the plasma etching process is CF₄, CHF₃ or nitrogen (N₂). In addition, N₂ acts only as a carrier and protective gas for CF₄ and CHF₃.

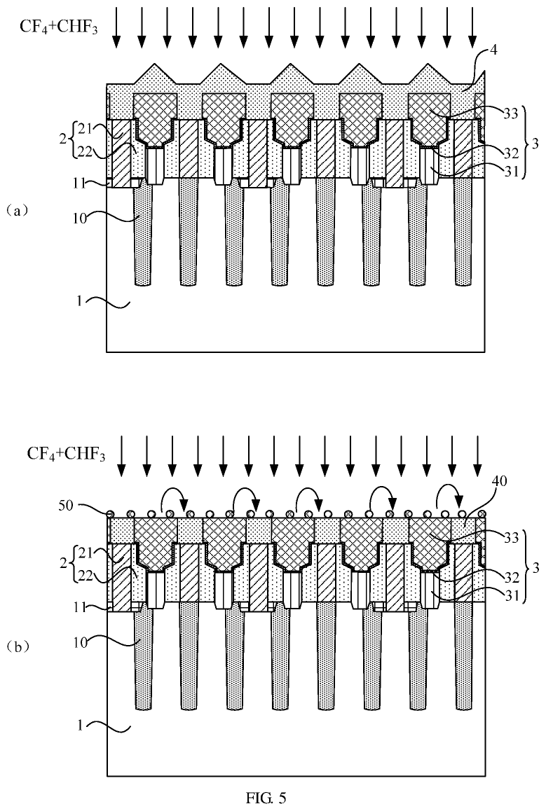

In some embodiments, with reference to FIG. 5, the dielectric layer 4 is generally etched in the following steps:

S131: Perform plasma etching on the dielectric layer 4 by using etching gases of CF₄ and CHF₃ to expose the contact pads 33, as shown in (a) of FIG. 5.

S132: Continue to perform the plasma etching on a remaining part of the dielectric layer 4 and exposed surfaces of the contact pads 33 by using etching gases of CF₄ and CHF₃ to fully remove a part of the dielectric layer 4 covering the surfaces of the contact pads 33, as shown in (b) of FIG. 5.

It can be understood that after the contact pads 33 are exposed. The continuous etching of the plasma is likely to damage exposed surfaces of the contact pads 33, causing etching residues 50 on the surfaces of the contact pads 33 and adjacent insulation portion 40. The composition of the etching residue 50 is related to the materials of the contact pad 33 and the dielectric layer 4 as well as the type of etching gas.

For example, the material of the contact pads 33 is W. The material of the insulation portion 40 is silicon nitride. The etching gases are CF₄ and CHF₃. The etching residue 50 includes W particles and/or tungsten nitride particles.

Because the etching gas is the oxygen-free etching gas, the etching residue 50 does not include tungsten oxide particles.

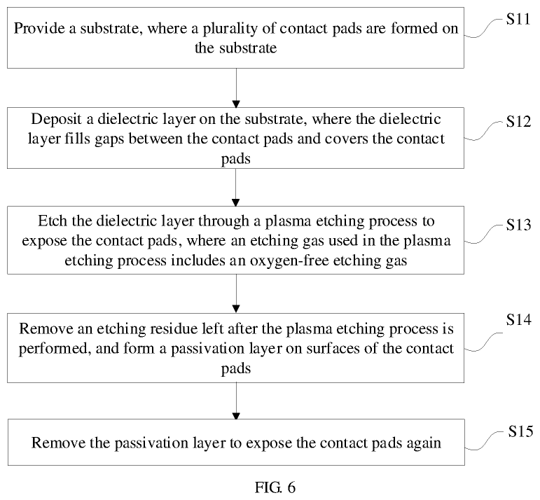

Based on this, with reference to FIG. 6, in some embodiments, after the contact pads are exposed, the manufacturing method of the semiconductor structure includes the following steps:

S14: Remove an etching residue left after the plasma etching process is performed, and form a passivation layer on surfaces of the contact pads.

S15: Remove the passivation layer to expose the contact pads again.

In the embodiment of the present disclosure, the plasma etching process is used to remove the etching residue, to avoid oxidation of etching residues to form oxides in subsequent process. The passivation layer is formed on the surfaces of the contact pads, to protect the exposed surfaces of the contact pads. Furthermore, the etching residue is caused by the damage on the surfaces of the contact pads. Therefore, removing the etching residue is beneficial to remove the damage on the surfaces of the contact pads.

In addition, after formed on the exposed surfaces of the contact pads, the entire passivation layer is removed, which is not only easy to implement, but also ensures that the exposed surfaces of the contact pads and the surfaces of the adjacent dielectric layers are clean without residual elemental particles, compound particles, or the like. Therefore, it can ensure better electrical properties of the contact pads, thereby ensuring the electrical properties of the semiconductor structure, and improving the use reliability of the semiconductor structure.

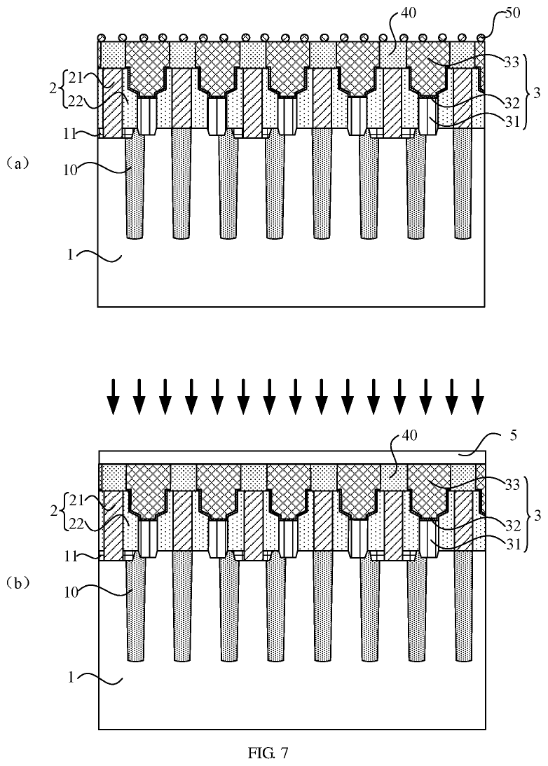

In step S14, with reference to S14 in FIG. 6 and FIG. 7, the step of removing the etching residue 50 left after the plasma etching process is performed, and forming the passivation layer 5 on surfaces of the contact pads 33 includes: performing a plasma bombardment on the contact pads 33 by using a plasma of a nitrogen-containing gas, to form the passivation layer 5 on the surfaces of the contact pads 33 when the etching residue 50 is removed.

In addition, the plasma bombardment performed on the contact pads 33 is enhanced, that is, the plasma bombardment with relatively large power is performed on the contact pads 33 by using a plasma of a nitrogen-containing gas with a relatively large flow rate. In this way, the etching residues 50 can be removed better, and the passivation layer 5 has a better film-forming quality, to subsequently remove the passivation layer 5 conveniently.

For example, in the process of performing the plasma bombardment on the contact pads 33 by using the plasma of the nitrogen-containing gas, the power of the plasma bombardment ranges from 100 w to 15,000 w. For example, the power of the plasma bombardment ranges from 100 w to 2,500 w, 2,500 w to 5,000 w, 5,000 w to 8,000 w, 8,000 w to 12,000 w, or 12,000 w to 15,000 w. In this embodiment, the power of the plasma bombardment ranges from 2,500 w to 5,000 w.

For example, in the process of performing the plasma bombardment on the contact pads 33 by using the plasma of the nitrogen-containing gas, the flow rate of the nitrogen-containing gas ranges from 100 sccm to 15,000 sccm. For example, the flow rate of the nitrogen-containing gas ranges from 100 sccm to 9,000 sccm, 3,000 to 12,000 sccm, 5,000 sccm to 12,000 sccm, 6,000 sccm to 13,000 sccm, or 8,000 sccm to 15,000 sccm. In this embodiment, the flow rate of the nitrogen-containing gas ranges from 8,000 sccm to 15,000 sccm.

In some embodiments, during the initial term or medium term of the plasma bombardment on the contact pads 33 by using the plasma of the nitrogen-containing gas, the flow rate of the nitrogen-containing gas is relatively high, for example, ranges from 8,000 sccm to 15,000 sccm, thereby nitriding the surface of the contact pads 33 by using the nitrogen-containing gas of a high flow rate, to form the passivation layer 5. During the final term of the plasma bombardment on the contact pads 33 by using the plasma of the nitrogen-containing gas, that is, after the passivation layer 5 forms a film stably, the flow rate of the nitrogen-containing gas may be adjusted to a relatively low state, for example, to be lower than 8,000 sccm. In some embodiments, during the final term of the plasma bombardment on the contact pads 33 by using the plasma of the nitrogen-containing gas, the flow rate of the nitrogen-containing gas ranges from 5,000 sccm to 6,000 sccm. In this way, the nitrogen-containing gas of a relatively low flow rate can be used to clean the reacted residues on the surface of the passivation layer 5.

For example, in the process of performing the plasma bombardment on the contact pads 33 by using the plasma of the nitrogen-containing gas, the pressure of the nitrogen-containing gas may be controlled in a range from 100 mTorr to 15,000 mTorr. For example, the pressure of the nitrogen-containing gas ranges from 100 mTorr to 800 mTorr, 800 mTorr to 1,000 mTorr, 1,000 mTorr to 3,000 mTorr, 3,000 mTorr to 5,000 mTorr, 5,000 mTorr to 10,000 mTorr, or 10,000 mTorr to 15,000 mTorr. In this embodiment, the pressure of the nitrogen-containing gas ranges from 800 mTorr to 1,000 mTorr.

Certainly, the ranges of the power of the plasma bombardment and the flow rate and the pressure of the nitrogen-containing gas are not limited to the foregoing description, but are limited to that the combination of the three ranges can ensure the stable manufacturing process of the semiconductor structure in a vacuum chamber.

In addition, the temperature of the plasma bombardment is related to the manufacturing temperature of the semiconductor structure.

For example, during the plasma bombardment on the contact pads 33 by using the plasma of the nitrogen-containing gas, a temperature of the plasma bombardment ranges from 25° C. to 300° C. For example, the temperature of the plasma bombardment ranges from 25° C. to 125° C., 125° C. to 150° C., 150° C. to 250° C., or 250° C. to 300° C. In this embodiment, the temperature of the plasma bombardment ranges from 150° C. to 250° C.

Similarly, the range of the temperature of the plasma bombardment is not limited to the foregoing description, but is limited to that it can ensure the stable manufacturing process of the semiconductor structure in a vacuum chamber.

It may be noted that after the plasma bombardment on the contact pads 33 by using the plasma of the nitrogen-containing gas, the formed passivation layer 5 is a nitride layer. In addition, the etching residue 50 can be removed through nitriding.

For example, the material of the contact pads 33 is W. The etching residue 50 includes W particles and/or tungsten nitride particles. After the plasma bombardment on the contact pads 33 by using the plasma of the nitrogen-containing gas, the formed passivation layer 5 is a tungsten nitride layer, which includes tungsten nitride obtained by nitriding the W particles and/or tungsten nitride particles. The passivation layer 5 is a tungsten nitride layer, such that the passivation layer can be cleaned and removed by using the diluted hydrofluoric acid solution (DHF) and deionized water (DIW).

In the foregoing examples, the nitrogen-containing gas can be set according to an actual requirement. For example, the nitrogen-containing gas is ammonia (NH₃) or N₂.

In some embodiments, the nitrogen-containing gas further includes a reducing gas. The reducing gas is, for example, hydrogen (H₂).

In some embodiments, the nitrogen-containing gas is a forming gas obtained by mixing H₂ and N₂. In addition, the volume ratio of H₂ in the forming gas is smaller than 5.7%, and is, for example, 5%, 4% or 3%.

In this way, oxides that may exist on the surface of the contact pad 33 can also be reduced by using the reducing gas in the nitrogen-containing gas, thereby avoiding generating oxides or removing existing oxides.

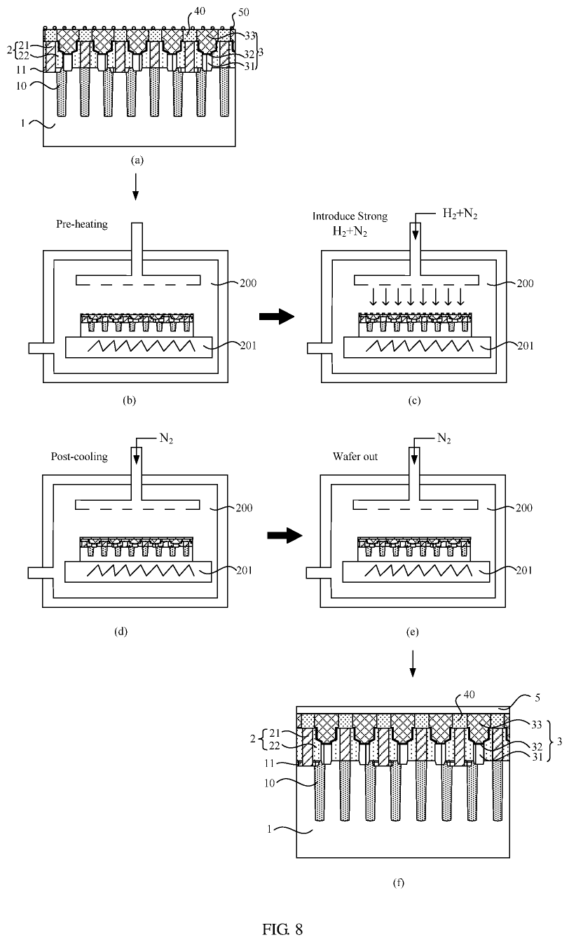

The semiconductor structure is always manufactured in the vacuum chamber. In some embodiments, as shown in FIG. 8, the etching residue 50 left after the plasma etching process is performed is removed, and the passivation layer 5 is formed on surfaces of the contact pads 33 in the following steps:

S141: A structure obtained after the contact pads 33 is exposed is located on a carrier 201 in a vacuum chamber 200, as shown in (a) and (b) of FIG. 8. Before the plasma bombardment is performed on the contact pads 33 by using the plasma of the nitrogen-containing gas, a structure obtained after the contact pads 33 are exposed is preheated.

In this case, the temperature and time for pre-heating may be set according to an actual requirement. This is not limited in the embodiments of the present disclosure.

S142: Perform a plasma bombardment of relatively large power on the contact pads 33 by using a plasma of a nitrogen-containing gas of a relatively large flow rate, to form the passivation layer 5 on the surfaces of the contact pads 33, as shown in (c) of the FIG. 8. For example, the power of the plasma bombardment ranges from 2,500 w to 5,000 w, and is 2,500 w, 3,500 w, 4,500 w or 5,000 w.

In this embodiment, the nitrogen-containing gas includes H₂ and N₂ and its initial flow rate ranges from 8,000 sccm to 15,000 sccm. The flow rate of the nitrogen-containing gas is 8,000 sccm, 10,000 sccm, 12,000 sccm or 15,000 sccm. After the passivation layer 5 forms a film stably, the flow rate of the nitrogen-containing gas ranges from 5,000 sccm to 8,000 sccm. The flow rate of the nitrogen-containing gas is 5,000 sccm, 6,000 sccm, 7,000 sccm, or 8,000 sccm.

For example, the pressure of the nitrogen-containing gas ranges from 800 mTorr to 1,000 mTorr. The pressure of the nitrogen-containing gas is 800 mTorr, 900 mTorr or 1000 mTorr.

For example, the temperature of the plasma bombardment ranges from 150° C. to 250° C. The temperature of the plasma bombardment is 150° C., 180° C., 220° C. or 250° C.

In the embodiments of the present disclosure, the ranges of the power and temperature of the plasma bombardment as well as the ranges of the flow rate and pressure of the nitrogen-containing gas are not limited to the foregoing description, but are specifically limited to that the stable manufacturing process of the semiconductor structure in the vacuum chamber can be ensured.

S143: Cool, after the plasma bombardment is performed on the contact pads 33 by using the plasma of the nitrogen-containing gas, a structure obtained after the passivation layer 5 is formed, as shown in (d) of FIG. 8.

In some embodiments, the structure obtained after the passivation layer 5 is formed is cooled in an inert gas environment. The inert gas environment is, for example, a N₂ environment.

S144: Take the structure obtained after the passivation layer 5 is formed out of the vacuum chamber 200, as shown in (e) and (f) of FIG. 8. The (f) in FIG. 8 shows the structure obtained after the passivation layer 5 is formed.

In the embodiment of the present disclosure, the structure obtained after the passivation layer 5 is formed is cooled and then is taken out of the vacuum chamber 200, which can avoid the generation of elemental particles and/or oxide particles on the surface of the passivation layer 5 because the structure that is obtained after the passivation layer 5 is formed and that is at a relatively high temperature is in direct contact with the air.

In addition, the N₂ environment can provide a safe cooling environment with low costs for the structure obtained after the passivation layer 5 is formed. For example, N₂ can purge the residual H₂ in the vacuum chamber 200, to avoid potential explosion hazards due to uncontrolled H₂ content, and also avoid introducing other by-products due to the presence of a mixed gas.

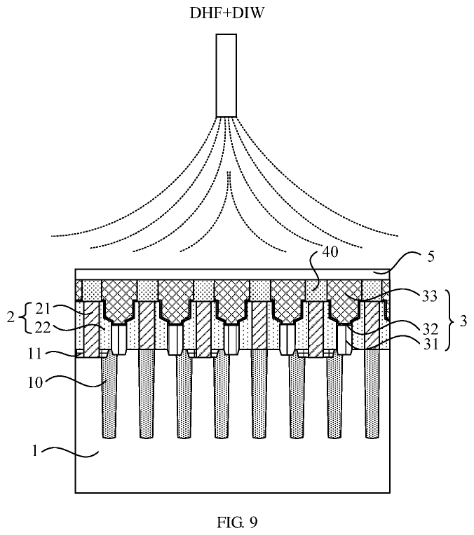

In step S15, with reference to S15 in FIG. 6 and FIG. 9, the passivation layer 5 is removed to expose the contact pads 33 again in the following steps: cleaning, by sequentially using DHF and DIW, a structure obtained after the passivation layer 5 is formed, to remove the passivation layer 5.

In some embodiments, in the DHF, a ratio of a volume of hydrofluoric acid to that of H₂O is 1:10 to 1:1,000.

For example, the ratio of the volume of hydrofluoric acid to that of H₂O may be 1:10, 1:20, 1:50, 1:100 or 1:1000.

The structure obtained after the passivation layer 5 is formed is cleaned by using DHF, to remove particles and natural oxide layers on the structure, and remove, for example, by-products remained after the previous process, particles adsorbed from the air, particles after the reaction of the gas in the vacuum chamber, and the like. Then, the structure obtained after the passivation layer 5 is formed is cleaned for seconds by using DIW, to effectively remove the passivation layer 5.

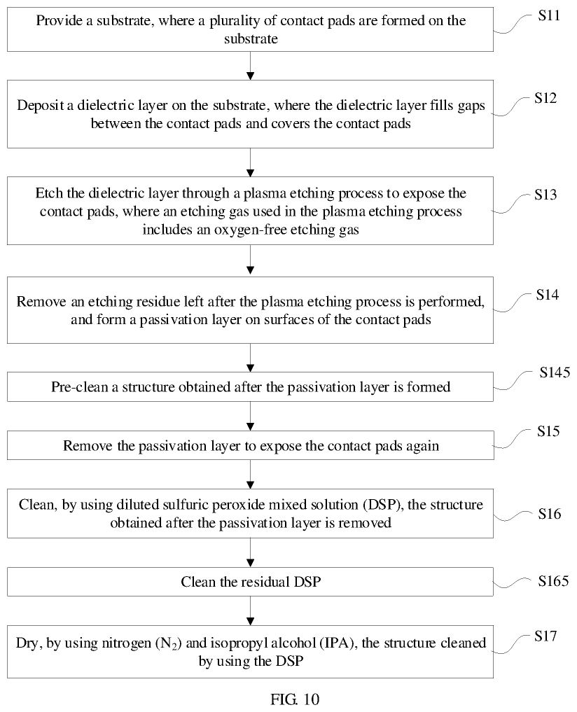

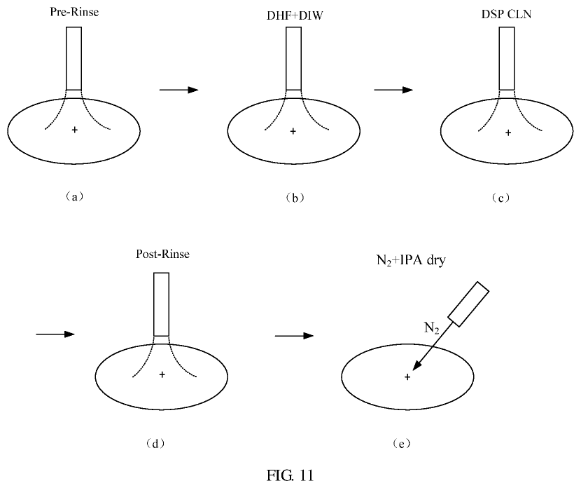

Based on this, with reference to FIG. 10 and FIG. 11, in some embodiments, after the passivation layer 5 is removed to expose the contact pads 33 again, the manufacturing method of a semiconductor structure further includes S16.

S16: Clean, by using diluted sulfuric peroxide mixed solution (DSP), the structure obtained after the passivation layer is removed, as shown in (c) of FIG. 11.

In some embodiments, the DSP includes: sulfuric acid (H₂SO₄), hydrogen peroxide (H₂O₂) and water (H₂O).

In some embodiments, a ratio of a total volume of the H₂SO₄ and the H₂O₂ to a volume of the H₂O is 1:5 to 1:1000. For example, the ratio of a total volume of the H₂SO₄ and the H₂O₂ to a volume of the H₂O may be 1:5, 1:10, 1:50, 1:100 or 1:1000.

In the embodiments of the present disclosure, the structure obtained after the passivation layer is removed is cleaned by using DSP, to further remove elemental particles generated by the plasma bombardment on the contact pads 33. For example, H₂SO₄ and H₂O₂ react to generate H₂SO₅. H₂SO₅ and H₂O₂ react to generate HSO₅ free radicals and OH free radicals. Because the energy level of the elemental particles (for example, W particles) generated by the plasma bombardment on the contact pads 33 jumps to a lower energy level, the elemental particles are easily taken away by HSO₅ radicals and OH radicals.

With reference to FIG. 10 and FIG. 11, in some embodiments, after the structure obtained after the passivation layer is removed is cleaned by using the DSP, the manufacturing method of the semiconductor structure further includes S17.

S17: Dry, by using N₂ and isopropyl alcohol (IPA), the structure cleaned by using the DSP, as shown in (e) of FIG. 11.

In the embodiments of the present disclosure, the structure cleaned by using the DSP is cleaned by using N₂ and IPA, to prevent the structure cleaned by using the DSP from being re-oxidized due to the residual water vapor.

With reference to FIG. 10 and FIG. 11, in some embodiments, before the passivation layer is removed, the manufacturing method of the semiconductor structure further includes S145.

S145: Pre-clean the structure obtained after the passivation layer is formed, as shown in (a) of FIG. 11.

The structure is pre-cleaned by using a standard cleaning solution such as at least one of a standard cleaning solution 1 (SC1) and a standard cleaning solution 2 (SC2). The SC1 is a mixture of ammonia, H₂O₂ and H₂O. The SC₂ is a mixture of hydrochloric acid, H₂O₂ and H₂O. Alternatively, the structure may be further cleaned by using ultra purified water (UPW).

As shown in (b) of FIG. 11, after wetted and pre-cleaned, the structure obtained after the passivation layer 5 is formed is cleaned by sequentially using DHF and DIW, to effectively remove the passivation layer 5.

In addition, with reference to FIG. 10 and FIG. 11, before the structure cleaned by using the diluted sulfur peroxide mixed solution is dried by using N₂ and IPA, the manufacturing method of a semiconductor structure further includes S165.

S165: Clean the residual DSP, as shown in (d) of FIG. 11.

For example, the residual DSP and the other possible residual chemicals are cleaned by using UPW.

The cleaning processes related to the embodiments of the present disclosure can be all achieved by using single-piece rotary or batch rotary spray cleaners or in another manner.

An embodiment of the present disclosure further provides a semiconductor structure, which is manufactured by using the manufacturing method in the foregoing embodiments.

As show in FIG. 4, the semiconductor structure includes a substrate 1, a plurality of bit lines 2, and a plurality of memory node contact structures 3.

Shallow trench isolation structures 10 are disposed in the substrate 1. The shallow trench isolation structures 10 separate a plurality of active regions arranged in an array in the substrate 1. The active regions include source regions and drain regions. The shallow trench isolation structure 10 is, for example, a SiO₂ isolation structure. A material of the active regions is, for example, poly-Si. The source and drain regions of the active regions are respectively different doped regions of poly-Si.

The bit lines 2 are formed on the substrate 1, and each include a bit line structure 21 and a sidewall structure 22. The bit line structure 21 includes: a conductive portion coupled to the source region correspondingly, and an insulating medium covering the top surface of the conductive portion. The sidewall structure 22 includes at least one insulating dielectric layer. The materials of the insulating medium and the insulating dielectric layer are, for example, SiO2 and/or silicon nitride (Si₃N₄).

With reference to FIG. 4, bottoms of some bit line structures 21 protrude into the substrate 1 to be coupled to the corresponding source regions, and the peripheral sides of the bottoms of the bit line structures 21 are also provided with insulating layers 11 filled in the substrate 1. The insulating layer 11 is, for example, a SiO₂ layer or a Si₃N₄ layer. The insulating layer 11 can be used for insulating the bit line structure 21 and the word line buried in the substrate 1.

The memory node contact structure 3 is formed between adjacent bit lines 2. The memory node contact structure 3 includes a contact plug 31, an adhesive layer 32 and the contact pad 33. The contact plug 31 is correspondingly coupled to the drain region, and the material of the contact plug 31 may include but is not only limited to poly-Si. The adhesive layer 32 is located between the contact pad 33 and the contact plug 31 and between the contact pad 33 and the sidewall structure 22 of the bit line 2. The material of the adhesive layer 32 may include but is not only limited to TiN.

The top surface of the contact pad 33 is higher than that of the bit line 2, and the insulation portion 40 insulates adjacent contact pads 33. The material of the contact pad 33 is, for example at least one from the group consisting of poly-Si, W, Co, Mo, Ta, Ti, Ru, Rh, Cu, Fe, Mn, V, Nb, Hf, Zr, Y, Al, Sn, Cr and La.

In some embodiments, a material of the contact pad 33 is W.

In the embodiments of the present disclosure, the semiconductor structure is manufactured by using the manufacturing method in some of the foregoing embodiments, to make the exposed surface of the contact pad 33 smooth and flat, avoid the generation of oxides on the contact pads 33, and avoid residual conductive elemental particles or compound particles on surfaces of the contact pads 33 and the adjacent insulation portion 40. In this way, it is beneficial to eliminate the damages on the surface of the contact pad 33, thereby ensuring electrical performance of the semiconductor structure and further improving the use reliability of the semiconductor structure.

The technical characteristics of the foregoing examples can be employed in arbitrary combinations. To provide a concise description of these examples, all possible combinations of all technical characteristics of the embodiment may not be described; however, these combinations of technical characteristics should be construed as disclosed in the description as long as no contradiction occurs.

Only several embodiments of the present application are described in detail above, but they should not therefore be construed as limiting the scope of the present application. It should be noted that those of ordinary skill in the art can further make variations and improvements without departing from the conception of the present application. These variations and improvements all fall within the protection scope of the present application. Therefore, the protection scope of the present application should be subject to the protection scope defined by the claims.

1. A manufacturing method of a semiconductor structure, comprising:
providing a substrate, wherein a plurality of contact pads are formed on the substrate;
depositing a dielectric layer on the substrate, wherein the dielectric layer fills gaps between the contact pads and covers the contact pads; and
etching the dielectric layer through a plasma etching process to expose the contact pads, wherein an etching gas used in the plasma etching process comprises an oxygen-free etching gas.

2. The manufacturing method of a semiconductor structure according to claim 1, wherein after the contact pads are exposed, the manufacturing method of a semiconductor structure further comprises:
removing an etching residue left after the plasma etching process is performed, and forming a passivation layer on surfaces of the contact pads; and
removing the passivation layer to expose the contact pads again.

3. The manufacturing method of a semiconductor structure according to claim 2, wherein
the removing an etching residue left after the plasma etching process is performed, and forming a passivation layer on surfaces of the contact pads comprises:
performing a plasma bombardment on the contact pads by using a plasma of a nitrogen-containing gas, to form the passivation layer on the surfaces of the contact pads when the etching residue is removed.

4. The manufacturing method of a semiconductor structure according to claim 3, wherein
the nitrogen-containing gas further comprises a reducing gas, wherein the reducing gas comprises hydrogen.

5. The manufacturing method of a semiconductor structure according to claim 3, wherein during the plasma bombardment on the contact pads by using the plasma of the nitrogen-containing gas, a power of the plasma bombardment ranges from 100 w to 15,000 w;
and a flow rate of the nitrogen-containing gas ranges from 100 sccm to 15,000 sccm.

6. The manufacturing method of a semiconductor structure according to claim 3, wherein during the plasma bombardment on the contact pads by using the plasma of the nitrogen-containing gas, a temperature of the plasma bombardment ranges from 25° C. to 300° C.

7. The manufacturing method of a semiconductor structure according to claim 3, wherein the removing an etching residue left after the plasma etching process is performed, and forming a passivation layer on surfaces of the contact pads, further comprises:
preheating, before the plasma bombardment is performed on the contact pads by using the plasma of the nitrogen-containing gas, a structure obtained after the contact pads are exposed; and
cooling, after the plasma bombardment is performed on the contact pads by using the plasma of the nitrogen-containing gas, a structure obtained after the passivation layer is formed.

8. The manufacturing method of a semiconductor structure according to claim 7, wherein the structure obtained after the passivation layer is formed is cooled in an inert gas environment.

9. The manufacturing method of a semiconductor structure according to claim 2, wherein the removing the passivation layer to expose the contact pads again comprises:
cleaning, by sequentially using diluted hydrofluoric acid solution and deionized water, a structure obtained after the passivation layer is formed, to remove the passivation layer.

10. The manufacturing method of a semiconductor structure according to claim 9, wherein in the diluted hydrofluoric acid solution, a ratio of a volume of hydrofluoric acid to a volume of water is 1:10 to 1:1,000.

11. The manufacturing method of a semiconductor structure according to claim 2, after the removing the passivation layer to expose the contact pads again, further comprising:
cleaning, by using diluted sulfuric peroxide mixed solution, the structure obtained after the passivation layer is removed.

12. The manufacturing method of a semiconductor structure according to claim 11, wherein the diluted sulfuric peroxide mixed solution comprises: sulfuric acid, hydrogen peroxide and water.

13. The manufacturing method of a semiconductor structure according to claim 12, wherein a ratio of a total volume of the sulfuric acid and the hydrogen peroxide to a volume of the water is 1:5 to 1:1,000.

14. The manufacturing method of a semiconductor structure according to claim 11, after the cleaning, by using diluted sulfuric peroxide mixed solution, the structure obtained after the passivation layer is removed, further comprising:
drying, by using nitrogen and isopropyl alcohol, the structure cleaned by using the diluted sulfuric peroxide mixed solution.

15. The manufacturing method of a semiconductor structure according to claim 14,
before the removing the passivation layer, further comprising: pre-cleaning the structure obtained after the passivation layer is formed; and
before the drying, by using nitrogen and isopropyl alcohol, the structure cleaned by using the diluted sulfuric peroxide mixed solution, further comprising: cleaning and removing the residual diluted sulfuric peroxide mixed solution.

16. The manufacturing method of a semiconductor structure according to claim 1, wherein the dielectric layer is a silicon nitride layer; and the etching gas used in the plasma etching process comprises:
carbon tetrafluoride and trifluoromethane; or
carbon tetrafluoride, trifluoromethane and chlorine.

17. The manufacturing method of a semiconductor structure according to claim 1, wherein
a material of the contact pads comprises at least one from the group consisting of polysilicon, tungsten, cobalt, molybdenum, tantalum, titanium, ruthenium, rhodium, copper, iron, manganese, vanadium, niobium, hafnium, zirconium, yttrium, aluminum, tin, chromium and lanthanum.

18. A semiconductor structure, manufactured by using the manufacturing method of a semiconductor structure according to claim 1.
